(19) United States
(12) Patent Application Publication
(10) Pub. No.: US 2024/0112740 A1
(43) Pub. Date: Apr. 4, 2024

(54) MEMORY CONTROLLER, MEMORY CONTROLLER CONTROL METHOD, AND MEMORY SYSTEM

(71) Applicant: Kioxia Corporation, Tokyo (JP)

(72) Inventors: Eriko AKAIHATA, Yamato Kanagawa (JP); Yasuyuki USHIJIMA, Yokohama Kanagawa (JP); Hisaki NIIKURA, Nakano Tokyo (JP)

(21) Appl. No.: 18/460,168

(22) Filed: Sep. 1, 2023

(30) Foreign Application Priority Data
Sep. 29, 2022 (JP) 2022-156792

(51) Int. Cl. G11C 16/16; G11C 16/08

(52) U.S. Cl. CPC G11C 16/16; G11C 16/08

(57) ABSTRACT

A memory controller includes an interface circuit and a processor. The interface circuit is connectable to a memory. The processor measures an erase time required to erase data from a memory via the interface circuit and measures a write time required to write data to the memory via the interface circuit. The processor controls a write time for a next write based on the measured erase time and measured write time.

### CROSS-REFERENCE TO RELATED APPLICATION(S)

This application is based upon and claims the benefit of priority from Japanese Patent Application No. 2022-156792, filed Sep. 29, 2022, the entire contents of which are incorporated herein by reference.

### FIELD

Embodiments described herein relate generally to a memory controller, a memory controller control method, and a memory system.

### BACKGROUND

A memory controller can control a write time required to write data to a memory by adjusting a write parameter, which is a parameter related to the write time. In this case, there is a problem in which there are variations in performance of a memory cell due to acquired factors. For example, if the write parameter is adjusted according to a worst condition of the performance of the memory cell, there is a problem such as a decrease in data write speed and a deterioration in memory Write/Erase (W/E) endurance.

### DESCRIPTION OF THE DRAWINGS

FIG. 1 is a block diagram illustrating a configuration of an information processing system according to a first embodiment.

FIG. 2 is a block diagram illustrating a functional configuration of a memory controller according to the first embodiment.

FIG. 3 is a block diagram illustrating a configuration of a memory unit according to the first embodiment.

FIG. 4 is a circuit diagram illustrating a configuration of a memory cell array according to the first embodiment.

FIGS. 5A and 5B are graphs illustrating changes over time of an erase time and a write time according to the first embodiment.

FIG. 6 is a flowchart illustrating an operation of a memory system according to the first embodiment.

FIG. 7 is a table for explaining an operation of the memory system according to the first embodiment.

FIG. 8 is a table illustrating write parameters according to the first embodiment.

FIG. 9 is a table for explaining an operation of a memory system according to a second embodiment.

FIG. 10 is a table illustrating write parameters according to the second embodiment.

### DETAILED DESCRIPTION

Embodiments provide a memory controller, a memory controller control method, and a memory system capable of appropriately controlling a write time required for a write of data to a memory.

In general, according to at least one embodiment, there is provided a memory controller including an interface circuit and a processor. The interface circuit is connectable to a memory. The processor is configured to measure an erase time required to erase data from the memory via the interface circuit. The processor is further configured to measure a write time required to write data to the memory via the interface circuit. The processor is further configured to control a write time for a next write based on the measured erase time and measured write time.

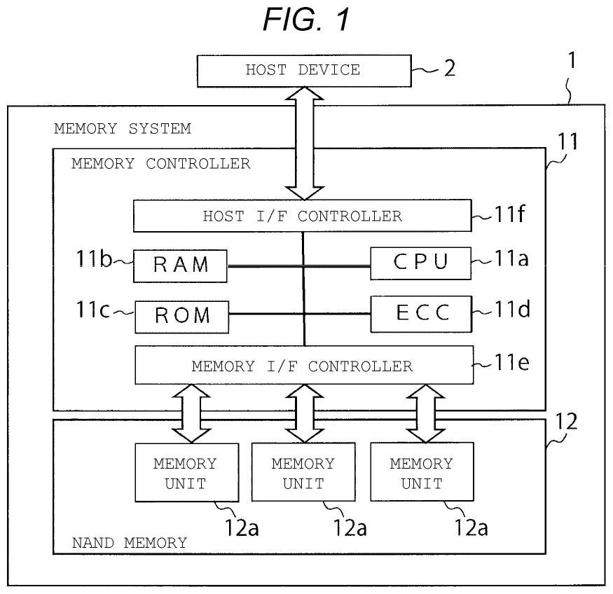

Hereinafter, embodiments of the present disclosure will be described with reference to the drawings. In FIGS. 1 to 10, the identical components are given the identical reference numerals.

### First Embodiment

FIG. 1 is a block diagram illustrating a configuration of an information processing system according to a first embodiment. FIG. 1 illustrates, as an example, a case where a NAND memory 12 includes three memory units 12a.

The information processing system according to the first embodiment includes a memory system 1 and a host device 2. The memory system 1 is, for example, a memory card, a universal flash storage (UFS), or a solid state drive (SSD). The memory system 1 functions, for example, as an external storage device for the host device 2. The host device 2 is, for example, an information processing apparatus such as a personal computer, a server device, or a mobile device. The host device 2 may issue an access request (read request, write (program) request, and erase request) to the memory system 1.

The memory system 1 has a memory controller 11 and the NAND memory 12.

The memory controller 11 controls various operations of the memory system 1. For example, the memory controller 11 controls a read of data from the NAND memory 12, based on the received read request. In addition, the memory controller 11 also controls a write of data to the NAND memory 12, based on the received write request. In addition, the memory controller 11 also controls an erase of data from the NAND memory 12, based on the received erase request. The memory controller 11 includes a central processing unit (CPU) 11a, a random access memory (RAM) lib, a read only memory (ROM) 11c, an error correcting code (ECC) circuit 11d, a memory interface (I/F) controller 11e, and a host I/F controller 11f. The memory controller 11 may further include a storage in which software is stored. The memory controller 11 may further include an electrical circuit (hardware) that executes an information process.

The CPU 11a is a processor that executes various programs. For example, firmware stored in the ROM 11c is loaded in the RAM lib, and executed by the CPU 11a. In addition, for example, software stored in the storage is loaded in the RAM 11b, and executed by the CPU 11a.

The RAM 11b is a volatile semiconductor memory from and to which data may be read and written. The RAM 11b provides a work area for the CPU 11a.

The ROM 11c is a semiconductor memory from which data may be read. The ROM 11c stores various types of data necessary for an operation of the CPU 11a.

The ECC circuit 11d is a circuit that performs an error correction process. The ECC circuit 11d performs encoding for error correction when data (write data) is written to the NAND memory 12. Thus, an error correction code is added to the write data. Further, when data is read from the NAND memory 12, the ECC circuit 11d performs error correction on the read data based on the error correction code added at a time of the data write. Thus, when the read data includes an error, it is possible to correct the error.

The memory I/F controller 11e is a circuit that manages an interface between the memory controller 11 and the NAND memory 12. The memory I/F controller 11e controls data transfer between the memory controller 11 and the NAND memory 12 under control of the CPU 11a.

The host I/F controller 11f is a circuit that manages an interface between the memory controller 11 and the host device 2. The host I/F controller 11f controls data transfer between the memory controller 11 and the host device 2 under the control of the CPU 11a.

The NAND memory 12 is, for example, a binary memory capable of storing two types of values in each memory cell. Alternatively, the NAND memory 12 is, for example, a multilevel memory capable of storing three or more types of values in each memory cell. For example, when the NAND memory 12 is a 16-level memory, each memory cell may store 16 types of values. The 16 types of values include, for example, values from 0 to 15 (0000 to 1111 in binary). The NAND memory 12 includes one or a plurality of memory units 12a. Each memory unit 12a has a memory cell array including a plurality of memory cells. The memory cell array functions as a memory region capable of storing data. Details of the memory cell array will be described below.

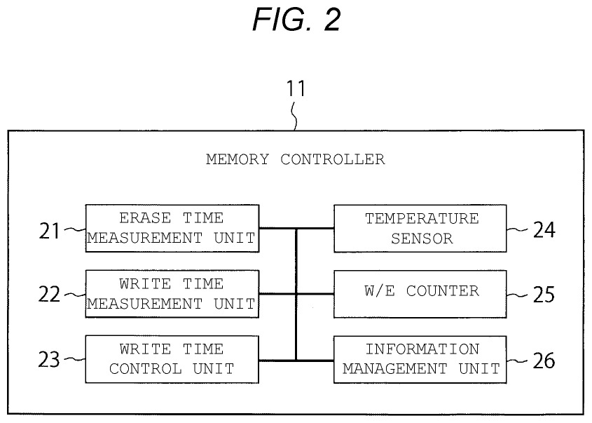

FIG. 2 is a block diagram illustrating a functional configuration of the memory controller 11 according to the first embodiment.

The memory controller 11 includes an erase time measurement unit 21, a write time measurement unit 22, a write time control unit 23, a temperature sensor 24, a W/E counter 25, and an information management unit 26. These functions may be implemented by any of firmware, software, and an electrical circuit. In addition, these functions may be implemented by combining two or more of the firmware, the software, and the electrical circuit. For example, firmware stored in the ROM 11c is loaded in the RAM lib, and executed by the CPU 11a to implement these functions. In addition, for example, the temperature sensor 24 according to the present embodiment is implemented by hardware that measures a temperature, and firmware, software, or an electrical circuit that controls this hardware.

The erase time measurement unit 21 measures an erase time required for erasing data from the NAND memory 12. The erase time measurement unit 21 measures the erase time for each block of the NAND memory 12, for example. In this case, the measured erase time represents a time required for erasing the data from all memory cells in each block.

The write time measurement unit 22 measures a write time required for writing data to the NAND memory 12. The write time measurement unit 22 measures the write time for each word line of the NAND memory 12, for example. In this case, the measured write time represents a time required for writing the data to all memory cells on each word line. Further, the write time measurement unit 22 may measure the write time for each word line group including a plurality of word lines.

The write time control unit 23 controls the write time of the data to the NAND memory 12, based on the erase time measured by the erase time measurement unit 21 and the write time measured by the write time measurement unit 22. Therefore, when the memory controller 11 writes data to the NAND memory 12, a write time required for writing the data is controlled to be a predetermined value by the write time control unit 23. The write time control unit 23 controls the write time for each word line of the NAND memory 12, for example.

In addition, the write time control unit 23 may also control a write time by adjusting various write parameters, which are parameters related to the write time. The write parameter includes, for example, a parameter related to a write voltage when writing data to the NAND memory 12 or a parameter related to a verification voltage when writing the data to the NAND memory 12. Examples of the write parameter are a voltage value of the write voltage, a voltage value of the verification voltage, a boosting timing of these voltages, and the like. More details of the write parameter will be described below.

In addition, the write time control unit 23 also may control the write time, based on the erase time measured by the erase time measurement unit 21, the write time measured by the write time measurement unit 22, and additional information which is information other than the erase time and the write time. Examples of the additional information are an address of a block of the NAND memory 12, the number of times of W/E of the NAND memory 12, a temperature of the NAND memory 12, a position of the NAND memory 12 in a wafer surface before dicing, and the like. More details of the additional information will be described below.

The temperature sensor 24 measures the temperature of the NAND memory 12. The temperature measured by the temperature sensor 24 is used, for example, as the additional information described above.

The W/E counter 25 counts the number of times of W/E of the NAND memory 12. The number of times of W/E counted by the W/E counter 25 is used, for example, as the additional information described above.

The information management unit 26 manages various types of information necessary for an operation of the memory controller 11 by storing the information in a memory region. The information management unit 26 manages, for example, information on each block of each memory unit 12a as block management information. Examples of the block management information are defect block determination information, a logical-to-physical address conversion table, a representative read threshold voltage (Vth) of each block, and the like. The information management unit 26 may further manage information on the position of each memory unit 12a on the wafer surface before dicing to use the information as the additional information.

Here, more details of the write time control unit 23 will be described.

The write time control unit 23 may control a write time by adjusting various write parameters. In this case, there is a problem in which there are variations in performance of the memory cell of the NAND memory 12 due to acquired factors. For example, if the write parameter is adjusted according to a worst condition of the performance of the memory cell, there is a problem such as a decrease in data write speed and a deterioration in W/E endurance of the NAND memory 12.

Therefore, the write time control unit 23 according to at least one embodiment adjusts the write parameter, based on an erase time measured by the erase time measurement unit 21 and a write time measured by the write time measurement unit 22. As the number of times of W/E of the NAND memory 12 is increased, a wear level of the NAND memory 12 is increased, and generally the erase time is increased. Therefore, by measuring the erase time, it becomes possible to know the wear level from the erase time, and it becomes possible to adjust the write parameter according to the wear level. With at least one embodiment, by adjusting the write parameter based on the measured erase time, it is possible to control the write time to reduce the problem described above, for example. In other words, with at least one embodiment, the write time may be appropriately controlled by adjusting the write parameter to an optimum value. Further, the measured write time is used, for example, as a reference value for shortening or extending the write time.

The erase time is measured for each block, for example. Thus, it is possible to know a wear level of each block from the erase time of each block. Meanwhile, the write time is measured for each word line in each block, for example. Thus, it is possible to set a reference value for shortening or extending the write time for each word line. In this case, the write time control unit 23 according to the present embodiment adjusts the write parameter for each word line, based on the erase time of each block measured by the erase time measurement unit 21 and the write time of each word line measured by the write time measurement unit 22. Thus, it is possible to adjust the write parameter of each word line to the optimum value according to the wear level of each block.

The write time control unit 23 may control the write time, based on the measured erase time, the measured write time, and additional information. Examples of the additional information are an address of a block of the NAND memory 12, the number of times of W/E of the NAND memory 12, a temperature of the NAND memory 12, a position of the NAND memory 12 in a wafer surface before dicing, and the like.

The address of the block is used, for example, to specify a distance between the block and a sense amplifier. The reason is that the write time for each block is affected by the distance between each block and the sense amplifier. In this case, the write time control unit 23 may change the write time, based on the distance between each block and the sense amplifier.

The number of times of W/E is used, for example, to specify the wear level of the NAND memory 12, as described above. Therefore, the write time control unit 23 may change the write time, based on the number of times of W/E counted by the W/E counter 25.

The temperature of the NAND memory 12 may affect the write time. Therefore, the write time control unit 23 may change the write time, based on the temperature measured by the temperature sensor 24.

The position of the NAND memory 12 on the wafer surface before dicing may also affect the write time. For example, the memory unit 12a manufactured from a region near a center portion of the wafer and the memory unit 12a manufactured from a region near an end portion of the wafer may have different characteristics for the write time. Therefore, the write time control unit 23 may change the write time, based on information on the position at the wafer surface managed by the information management unit 26.

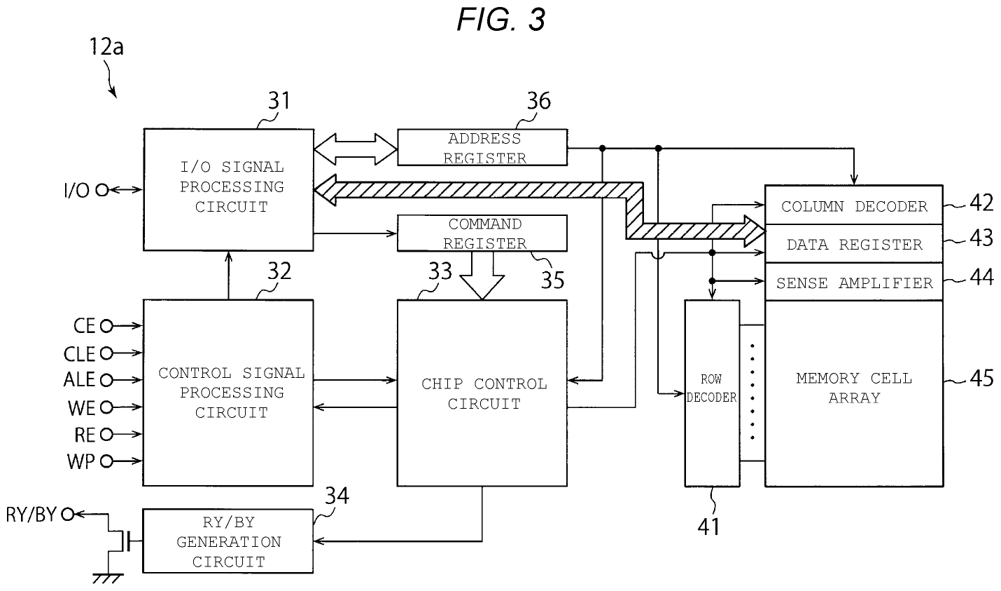

FIG. 3 is a block diagram illustrating a configuration of the memory unit 12a according to the first embodiment.

Each memory unit 12a according to the present embodiment includes an input/output (I/O) signal processing circuit 31, a control signal processing circuit 32, a chip control circuit 33, an RY/BY generation circuit 34, a command register 35, an address register 36, a row decoder 41, a column decoder 42, a data register 43, a sense amplifier 44, and a memory cell array 45.

The I/O signal processing circuit 31 is a buffer circuit that processes an input signal to the memory unit 12a and an output signal from the memory unit 12a. A command, an address, and data latched by the I/O signal processing circuit 31 are distributed to the command register 35, the address register 36, and the data register 43, respectively.

The control signal processing circuit 32 is a circuit that processes a control signal to the memory unit 12a. The control signal processing circuit 32 controls the distribution described above by the I/O signal processing circuit 31, based on the control signal to the memory unit 12a. The control signal input to the control signal processing circuit 32 is, for example, a chip enable (CE) signal, a command latch enable (CLE) signal, an address latch enable (ALE) signal, a write enable (WE) signal, a read enable (RE) signal, a write protest (WP) signal, or the like. The control signal processing circuit 32 also transfers the control signal to the chip control circuit 33.

The chip control circuit 33 is a circuit that controls a memory chip (memory unit 12a). The chip control circuit 33 controls an operation of the memory unit 12a, based on the control signal transferred from the control signal processing circuit 32. An operation mode of the chip control circuit 33 is changed, for example, when a state of the chip control circuit 33 transitions according to the control signal.

The RY/BY generation circuit 34 is a circuit that outputs a ready (RY) signal and a busy (BY) signal. The RY/BY generation circuit 34 selectively outputs the RY signal and the BY signal under control of the chip control circuit 33. The RY signal is output when the memory unit 12a is not operating (ready state). The BY signal is output when the memory unit 12a is in operation (busy state).

The command register 35 is a register that stores a command. The command stored in the command register 35 is read by the chip control circuit 33.

The address register 36 is a register that stores an address. The address stored in the address register 36 is read by the chip control circuit 33, the row decoder 41, and the column decoder 42.

The row decoder 41 is a decoder that controls a word line of the memory cell array 45. The row decoder 41 applies a voltage to the word line of the memory cell array 45, based on a row address read from the address register 36.

The column decoder 42 is a decoder that controls a latch circuit of the data register 43. The column decoder 42 selects the latch circuit of the data register 43, based on a column address read from the address register 36.

The data register 43 is a register that stores data. The data register 43 stores data from the I/O signal processing circuit 31 and data from the sense amplifier 44.

The sense amplifier 44 is an amplifier that performs an operation on a bit line of the memory cell array 45. The sense amplifier 44 senses data read to the bit line of the memory cell array 45. The row decoder 41, the column decoder 42, the data register 43, and the sense amplifier 44 function as interfaces for a read operation, a write operation, and an erase operation for the memory cell array 45.

The memory cell array 45 is a region in which a plurality of memory cells are arranged in an array shape. The memory cell array 45 functions as a memory region capable of storing data. The NAND memory 12 according to at least one embodiment is a three-dimensional semiconductor memory in which these memory cells are arranged in a three-dimensional array shape. More details of the memory cell array 45 will be described below.

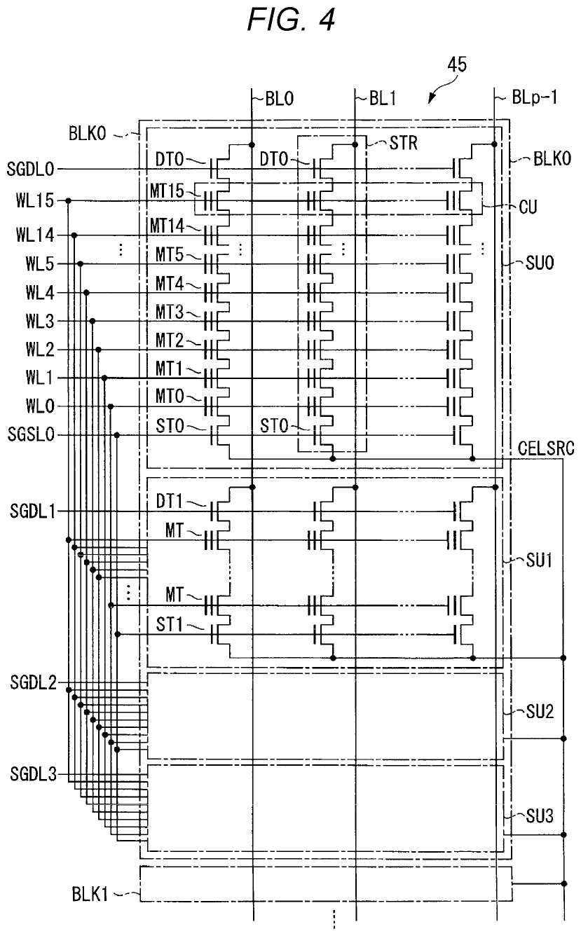

FIG. 4 is a circuit diagram illustrating a configuration of the memory cell array 45 according to the first embodiment.

The memory cell array 45 includes a plurality of blocks. FIG. 4 illustrates a block BLK0 and a block BLK1, as an example of the plurality of blocks. Hereinafter, a configuration of the block according to at least one embodiment will be described by using the block BLK0 as a subject.

The block BLK0 includes, for example, a plurality of string units SU0 to SU3. Each of the string units SU0 to SU3 includes p NAND strings STR (p is an integer equal to or more than 2) between p bit lines BL0 to BLp-1 and a cell source line CELSRC. For example, in string unit SU0, the NAND string STR between the bit line BL0 and the cell source line CELSRC includes memory cell transistors (memory cells) MT0 to MT15 on word lines WL0 to WL15, and select transistors (select gates) ST0 on select line SGSL0 and DT0 on select line SGDL0. The select line SGSL0 is called a source-side select line. The select line SGDL0 is called a drain-side select line. In the at least one embodiment, the other NAND string STR has a similar structure.

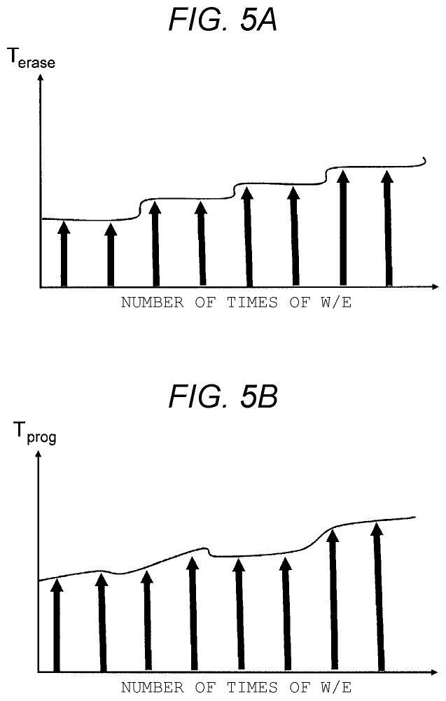

FIGS. 5A and 5B are graphs illustrating changes over time of an erase time Tₑᵣₐₛₑ and a write time T_{prog} according to the first embodiment.

FIG. 5A illustrates a change of the erase time Tₑᵣₐₛₑ of a certain block according to the number of times of W/E. A vertical axis in FIG. 5A indicates the erase time Tₑᵣₐₛₑ measured by the erase time measurement unit 21. A horizontal axis of FIG. 5A indicates the number of times of W/E counted by the W/E counter 25. As described above, as the number of times of W/E of the NAND memory 12 is increased, a wear level of the NAND memory 12 is increased, and generally the erase time Tₑᵣₐₛₑ is increased.

FIG. 5B illustrates a change of the write time T_{prog} of a certain word line according to the number of times of W/E. A vertical axis in FIG. 5B indicates the write time T_{prog} measured by the write time measurement unit 22. A horizontal axis of FIG. 5B indicates the number of times of W/E counted by the W/E counter 25. The write time T_{prog} according to at least one embodiment is changed according to the wear level of the NAND memory 12, and is also changed according to the control by the write time control unit 23.

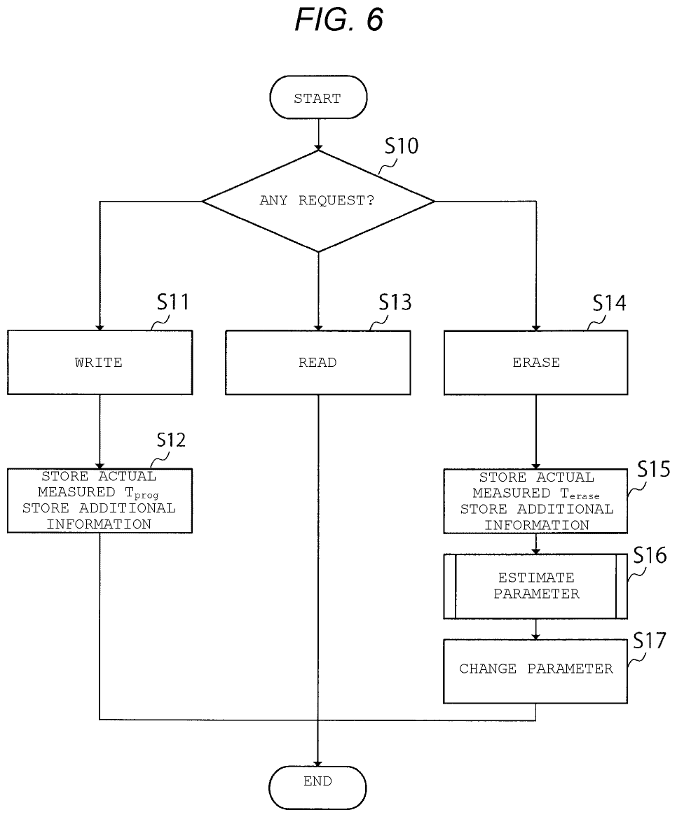

Next, more details of the operation of the memory system 1 according to the first embodiment will be described with reference to FIGS. 6 to 8. FIGS. 6 to 8 illustrate operation examples of the memory system 1 when a use period of the NAND memory 12 is short and a wear level of the NAND memory 12 is low.

FIG. 6 is a flowchart illustrating an operation of the memory system 1 according to the first embodiment.

When receiving a request (start), the memory system 1 determines a content of the received request (S10).

In a case of receiving a write request, the memory system 1 writes data (S11).

When writing data, the memory system 1 causes the write time measurement unit 22 to measure a write time required for writing the data for each word line, and stores the measured write time (actual measured T_{prog}) into the NAND memory 12 (S12). In addition, when writing the data, the memory system 1 measures additional information for each word line, and stores the measured additional information into the NAND memory 12. After the process in S12, the memory system 1 ends a series of processes in FIG. 6 (end).

In a case of receiving a read request, the memory system 1 reads data (S13). After the process in S13, the memory system 1 ends the series of processes in FIG. 6 (end).

In a case of receiving an erase request, the memory system 1 erases data (S14).

When erasing data, the memory system 1 causes the erase time measurement unit 21 to measure an erase time required for erasing the data for each block, and stores the measured erase time (actual measured Tₑᵣₐₛₑ) into the NAND memory 12 (S15). In addition, when erasing the data, the memory system 1 measures additional information for each block, and stores the measured additional information into the NAND memory 12.

After that, the memory system 1 estimates a write parameter based on the erase time, the write time, and the additional information stored in the NAND memory 12 (S16). Details of the process in S16 will be described below.

The memory system 1 causes the write time control unit 23 to change the write parameter for each word line, based on a result of the process in S16 (S17). Thus, the write time is changed for each word line. After the process in S17, the memory system 1 ends the series of processes in FIG. 6 (end).

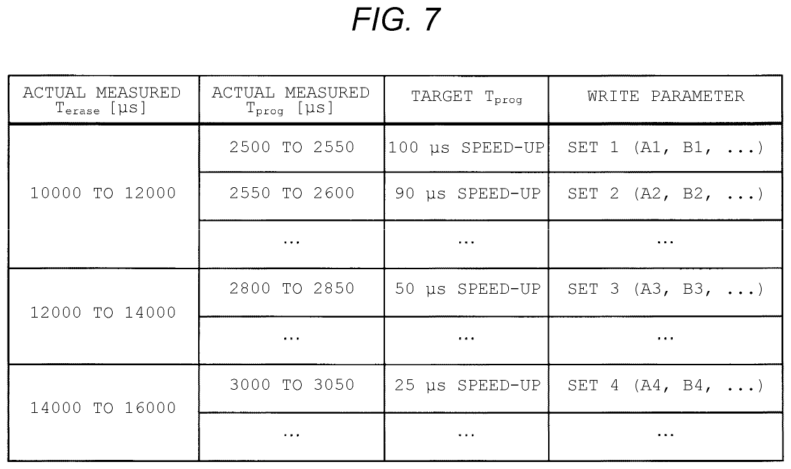

FIG. 7 is a table for explaining an operation of the memory system 1 according to the first embodiment. The operation described by using FIG. 7 is an example of the process in S16.

FIG. 7 illustrates the actual measured Tₑᵣₐₛₑ, the actual measured T_{prog}, a target T_{prog}, and a write parameter. The actual measured Tₑᵣₐₛₑ is an erase time measured by the erase time measurement unit 21. The actual measured T_{prog} is a write time measured by the write time measurement unit 22. The target T_{prog} is a write time set by the write time control unit 23. The write parameter includes a parameter set such as a parameter A, a parameter B, and the like. The table illustrated in FIG. 7 is managed in the NAND memory 12 by the information management unit 26.

The table illustrated in FIG. 7 includes a plurality of numerical value ranges of actual measured Tₑᵣₐₛₑ and a plurality of numerical value ranges of actual measured T_{prog}. These numerical value ranges are examples of a first numerical value range and a second numerical value range, respectively.

For example, when the actual measured Tₑᵣₐₛₑ is 11000 μs and the actual measured T_{prog} is 2520 μs, the actual measured Tₑᵣₐₛₑ belongs to a numerical value range “10000 to 12000 μs” and the actual measured T_{prog} belongs to a numerical value range “2500 to 2550 μs”. In this case, the target T_{prog} becomes 2420 μs by speeding up the actual measured T_{prog} by 100 μs. This value of 100 μs corresponds to a shortening quantity in write time from 2520 μs to 2420 μs. Such speed-up is achieved by adjusting the write parameter to a set 1. For example, a value of the parameter A is adjusted to “A1”, and a value of the parameter B is adjusted to “B1”. Thus, the target T_{prog} becomes 2420 μs.

When the actual measured Tₑᵣₐₛₑ and the actual measured T_{prog} are input, the write time control unit 23 specifies a numerical value range to which the actual measured Tₑᵣₐₛₑ belongs, and further specifies a numerical value range to which the actual measured T_{prog} belongs. For example, when the actual measured Tₑᵣₐₛₑ is 11000 μs and the actual measured T_{prog} is 2520 μs, as the numerical value range to which the actual measured Tₑᵣₐₛₑ belongs, “10000 to 12000 μs” is specified, and as the numerical value range to which the actual measured T_{prog} belongs, “2500 to 2550 μs” is specified.

In the present embodiment, these numerical value ranges are managed with a tree structure. For example, a plurality of numerical value ranges of the actual measured T_{prog} exist under the numerical value range of the actual measured Tₑᵣₐₛₑ “10000 to 12000 μs”. The numerical value range “2500 to 2550 μs” for the actual measured T_{prog} is one of the plurality of numerical value ranges. Therefore, the write time control unit 23 according to the present embodiment first specifies the numerical value range to which the actual measured Tₑᵣₐₛₑ belongs, and then specifies the numerical value range to which the actual measured T_{prog} belongs based on the numerical value range to which the actual measured Tₑᵣₐₛₑ belongs.

The write time control unit 23 determines the target T_{prog}, based on the numerical value range to which the actual measured Tₑᵣₐₛₑ belongs and the numerical value range to which the actual measured T_{prog} belongs. For example, when the actual measured Tₑᵣₐₛₑ is 11000 μs and the actual measured T_{prog} is 2520 μs, the target T_{prog} becomes 2420 μs by speeding up the actual measured T_{prog} by 100 μs. The target T_{prog} according to the present embodiment may be used as a setting value for feedback control such as proportional integral differential (PID) control, for example. In this case, the write time control unit 23 controls a write time such that the write time approaches the target T_{prog}.

The table illustrated in FIG. 7 illustrates the numerical value ranges of the actual measured Tₑᵣₐₛₑ and the actual measured T_{prog} when a use period of the NAND memory 12 is short and a wear level of the NAND memory 12 is low. When the wear level of the NAND memory 12 is low, the faster the write speed, the more efficient use of the NAND memory 12 in many cases. Thus, the table illustrated in FIG. 7 illustrates various examples of speeding up the target T_{prog}.

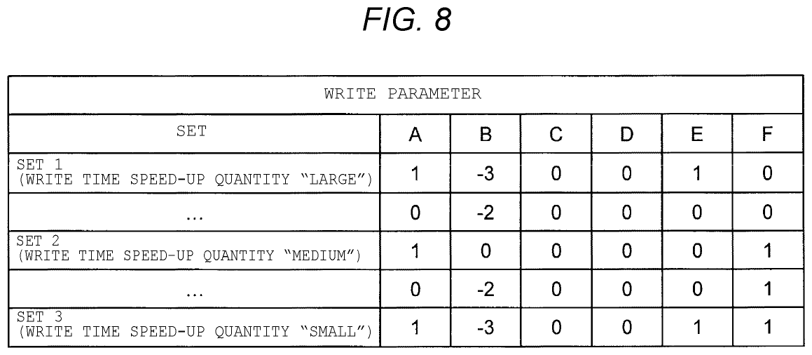

FIG. 8 is a table illustrating write parameters according to the first embodiment.

FIG. 8 illustrates various sets of write parameters and the values of the parameters A to F in each set. For example, when the write parameter is adjusted to the set 1, the values of the parameters A, B, C, D, E, and F are adjusted to “1”, “−3”, “0”, “0”, “1”, and “0”, respectively. The parameters A to F include, for example, a voltage value of a write voltage, a voltage value of a verification voltage, a boosting timing of these voltages, and the like. When designing these sets, a statistical analysis is performed on data acquired before shipment of the memory system 1, and based on these statistical analyses, various values for a speed-up quantity of write time (target T_{prog}) are determined. The speed-up quantity of write time is a value obtained by subtracting the actual measured T_{prog} from the target T_{prog}. These speed-up quantities are stored into the NAND memory 12 in a form of the table illustrated in FIG. 7 before shipment. When the memory system 1 operates after shipment, the memory system 1 may speed up a write while suppressing an increase in the number of error bits, by adopting these speed-up quantities.

FIG. 8 illustrates sets 1 to 3 as examples of various sets of write parameters. The set 1 corresponds to a set with which a speed-up quantity of write time is large. The set 2 corresponds to a set with which the speed-up quantity of write time is medium. The set 3 corresponds to a set with which the speed-up quantity of write time is small. For example, the speed-up quantities for the sets 1, 2, and 3 are “100 μs”, “90 μs”, and “50 μs”, respectively. Further, the speed-up quantities of write time of “large” and “small” mean that the speed-up quantities of write time are “large” and “small”, as compared to an average value of the speed-up quantities of write time. In addition, the speed-up quantity of write time of “medium” means that the speed-up quantity of write time is “close to” the average value of the speed-up quantities of write time.

As described above, the memory controller 11 according to at least one embodiment controls the write time of data to the NAND memory 12, based on the measured erase time and write voltage. Therefore, with at least one embodiment, it is possible to appropriately control the write time when writing data to the NAND memory 12. For example, it is possible to speed up the write while suppressing an increase in the number of error bits.

### Second Embodiment

A second embodiment is an operation example of the memory system 1 when a use period of the NAND memory 12 is long and a wear level of the NAND memory 12 is high. The memory system 1 according to the second embodiment has the same configuration as the memory system 1 according to the first embodiment. Therefore, the contents described with reference to FIGS. 1 to 5 are applied not only to the first embodiment but also to the second embodiment.

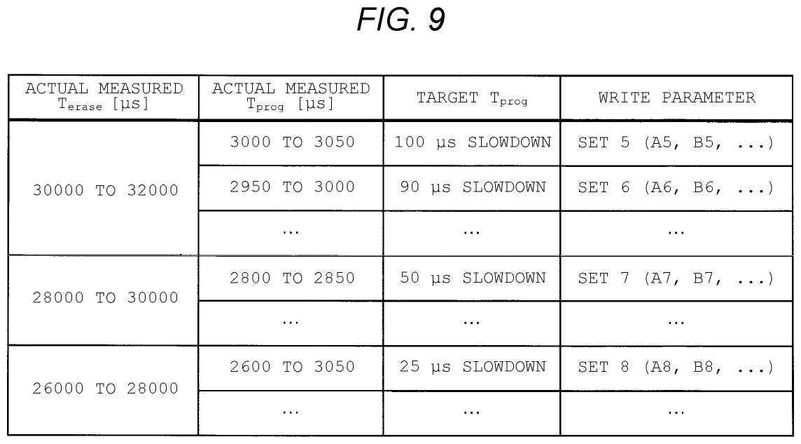

FIG. 9 is a table for explaining an operation of the memory system 1 according to the second embodiment. The operation described using FIG. 9 is an example of the process in S16.

In the same manner as FIG. 7, FIG. 9 illustrates the actual measured Tₑᵣₐₛₑ, the actual measured T_{prog}, the target T_{prog}, and a write parameter. The table illustrated in FIG. 9 also includes a plurality of numerical value ranges of the actual measured Tₑᵣₐₛₑ and a plurality of numerical value ranges of the actual measured T_{prog}.

For example, when the actual measured Tₑᵣₐₛₑ is 29000 μs and the actual measured T_{prog} is 2820 μs, the actual measured Tₑᵣₐₛₑ belongs to the numerical value range “28000 to 30000 μs” and the actual measured T_{prog} belongs to the numerical value range “2800 to 2850 μs”. In this case, the target T_{prog} is slowed down by 50 μs from the actual measured T_{prog} to be 2870 μs. This value of 50 μs corresponds to an extension quantity of write time from 2820 μs to 2870 μs. Such slowdown is achieved by adjusting the write parameter to set 7. For example, a value of the parameter A is adjusted to “A7” and a value of the parameter B is adjusted to “B7”. Thus, the target T_{prog} becomes 2870 μs.

An operation of the write time control unit 23 according to the present embodiment has the same manner as the operation of the write time control unit 23 according to the first embodiment. When the actual measured Tₑᵣₐₛₑ and the actual measured T_{prog} are input, the write time control unit 23 according to the present embodiment specifies a numerical value range to which the actual measured Tₑᵣₐₛₑ belongs, and further specifies a numerical value range to which the actual measured T_{prog} belongs. For example, when the actual measured Tₑᵣₐₛₑ is 29000 μs and the actual measured T_{prog} is 2820 μs, as the numerical value range to which the actual measured Tₑᵣₐₛₑ belongs, “28000 to 30000 μs” is specified, and as the numerical value range to which the actual measured T_{prog} belongs, “2800 to 2850 μs” is specified. As a result, the target T_{prog} is slowed down by 50 μs from the actual measured T_{prog} to be 2870 μs.

The table illustrated in FIG. 9 illustrates the numerical value ranges of the actual measured Tₑᵣₐₛₑ and the actual measured T_{prog} when a use period of the NAND memory 12 is long and a wear level of the NAND memory 12 is high. When the wear level of the NAND memory 12 is high, the slower the write speed, the more efficient use of the NAND memory 12 in many cases. Thus, the table illustrated in FIG. 9 illustrates various examples of slowing down the target T_{prog}.

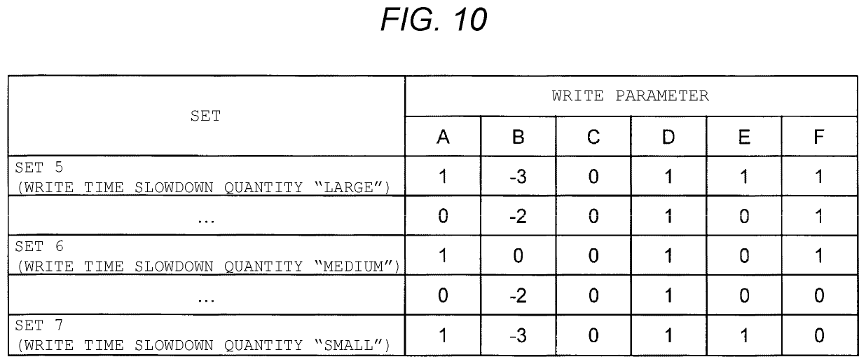

FIG. 10 is a table illustrating write parameters according to the second embodiment.

In the same manner as FIG. 8, FIG. 10 illustrates various sets of write parameters and the values of the parameters A to F in each set. When designing these sets, a statistical analysis is performed on data acquired before shipment of the memory system 1, and based on these statistical analyses, various values for a slowdown quantity of write time (target T_{prog}) are determined. The slowdown quantity of write time is a value obtained by subtracting the target T_{prog} from the actual measured T_{prog}. These slowdown quantities are stored into the NAND memory 12 in a form of the table illustrated in FIG. 9 before shipment. When the memory system 1 operates after shipment, the memory system 1 may slow down a write while maximizing an effect of improving a W/E breakdown voltage by adopting these slowdown quantities.

FIG. 10 illustrates sets 5 to 7 as examples of various sets of write parameters. The set 5 corresponds to a set with which a slowdown quantity of write time is large and the effect of improving the W/E breakdown voltage is large. The set 2 corresponds to a set with which the slowdown quantity of write time is medium and the effect of improving the W/E breakdown voltage is medium. The set 3 corresponds to a set with which the slowdown quantity of write time is small and the effect of improving the W/E breakdown voltage is small. For example, the slowdown quantities for the sets 5, 6, and 7 are 100 μs, 90 μs, and 50 μs, respectively. Further, the slowdown quantities of write time of “large” and “small” mean that the slowdown quantities of write time are “larger” and “smaller” than an average value of the slowdown quantities of write time. In addition, the slowdown quantity of write time of “medium” means that the slowdown quantity of write time is “close to” the average value of the slowdown quantities of write time.

As described above, the memory controller 11 according to at least one embodiment controls the write time of the data to the NAND memory 12, based on the measured erase time and write voltage. Therefore, with at least one embodiment, it is possible to appropriately control the write time when writing the data to the NAND memory 12. For example, it is possible to slow down the write while maximizing the effect of improving the W/E breakdown voltage.

Further, the memory system 1 according to the second embodiment may include both the table illustrated in FIG. 7 and the table illustrated in FIG. 9. In this case, these tables may be integrated into one table. In this case, the memory system 1 according to the second embodiment speeds up the target T_{prog} from the actual measured T_{prog} based on the table illustrated in FIG. 7, and slows down the target T_{prog} from the actual measured T_{prog} based on the table illustrated in FIG. 9. Thus, with this memory system 1, it is possible to both speed up and slow down a write.

The embodiments are examples, and the scope of the disclosure is not limited thereto.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory controller comprising:
an interface circuit connectable to a memory; and
a processor configured to:
measure an erase time required to erase data from the memory via the interface circuit;
measure a write time required to write data to the memory via the interface circuit; and
control a write time for a next write based on the measured erase time and measured write time.

2. The memory controller according to claim 1,
wherein the memory includes a plurality of blocks, and
wherein the erase time is measured for each block of the memory.

3. The memory controller according to claim 1,
wherein the memory includes a plurality of word lines, and
wherein the write time is measured for each word line of the memory.

4. The memory controller according to claim 1,
wherein the processor is configured to control the write time by adjusting a write parameter, the write parameter being related to the write time.

5. The memory controller according to claim 4,
wherein the write parameter includes a parameter related to a write voltage or a verification voltage when writing data to the memory.

6. The memory controller according to claim 1,
wherein the processor is configured to control the write time based on the measured erase time and measured write time, and based on additional information different from the erase time and the write time.

7. The memory controller according to claim 6,
wherein the additional information includes information that affects a change of the erase time or the write time.

8. The memory controller according to claim 1,
wherein the processor is configured to specify a first numerical value range to which the erase time belongs among a plurality of first numerical value ranges, specify a second numerical value range to which the write time belongs among a plurality of second numerical value ranges, and control the write time based on the specified first numerical value range and specified second numerical value range.

9. The memory controller according to claim 8,
wherein the processor is further configured to control the write time by adjusting a write parameter, the write parameter being related to the write time, based on the specified first numerical value range and specified second numerical value range.

10. The memory controller according to claim 1,
wherein the processor is configured to shorten the write time, by a shortened amount, from the measured write time based on the measured erase time and measured write time.

11. The memory controller according to claim 10,
wherein the processor is further configured to change the shortened amount of the write time based on the measured erase time and measured write time.

12. The memory controller according to claim 1,
wherein the processor is configured to extend the write time, by an extended amount, from the measured write time based on the measured erase time and measured write time.

13. The memory controller according to claim 12,
wherein the processor is further configured to change the extended amount of the write time based on the measured erase time and measured write time.

14. A control method of a memory, the method comprising:
measuring an erase time required to erase data from the memory;
measuring a write time required to write data to the memory; and
controlling a write time for a next write based on the measured erase time and measured write time.

15. The control method according to claim 14, further comprising:
specifying a first numerical value range to which the erase time belongs among a plurality of first numerical value ranges, specifying a second numerical value range to which the write time belongs among a plurality of second numerical value ranges, and controlling the write time based on the specified first numerical value range and specified second numerical value range.

16. The memory controller control method according to claim 14, further comprising:
shortening the write time from the measured write time based on the measured erase time and measured write time.

17. The memory controller control method according to claim 14, further comprising:
extending the write time from the measured write time based on the measured erase time and measured write time.

18. A memory system comprising:
a memory including a plurality of memory cells; and
a processor configured to:
measure an erase time required to erase data from a part of the memory cells,
measure a write time required to write data to a part of the memory cells, and
control a write time for a next write based on the measured erase time and measured write time.

19. The memory system according to claim 18,
wherein the memory further includes a plurality of blocks, and
wherein the erase time is measured for each block of the memory.

20. The memory system according to claim 18,
wherein the memory further includes a plurality of word lines, and
wherein the write time is measured for each word line of the memory.
